(19) United States
(12) Patent Application Publication
(10) Pub. No.: US 2002/0142589 A1
(43) Pub. Date: Oct. 3, 2002

(54) Method of obtaining low temperature alpha-ta thin films using wafer bias

(75) Inventors: Arvind Sundarrajan, Santa Clara, CA (US); Suraj Rengarajan, San Jose, CA (US); Michael A. Miller, Sunnyvale, CA (US); Peijun Ding, San Jose, CA (US); Gongda Yao, Fremont, CA (US); Christophe Marcadal, Santa Clara, CA (US); Ling Chen, Sunnyvale, CA (US)

Correspondence Address: PATENT COUNSEL, APPLIED MATERIALS,INC, Legal Affairs Department, P.O.BOX 450A, Santa Clara, CA, 95052, US

(73) Assignee: Applied Materials, Inc.

(21) Appl. No.: 09/775,356

(22) Filed: Jan. 31, 2001

(51) Int. Cl. H01L 21/44

(52) U.S. Cl. 438/683

(57) ABSTRACT

Provided herein is a method of depositing alpha-tantalum film on a semiconductor wafer by depositing a tantalum nitride film on a wafer; and then depositing a tantalum film over the tantalum nitride film using wafer bias. The tantalum film as deposited is in alpha phase. Also provided is a method of depositing Cu barrier and seed layer on a semiconductor wafer, comprising the steps of depositing a tantalum nitride layer on a wafer; depositing a tantalum layer over the tantalum nitride layer using wafer bias, wherein the resulting tantalum barrier layer is in alpha phase; and then depositing Cu seed layer over the alpha-tantalum barrier layer. Further provided is a method of depositing alpha-tantalum film/layer using two-chamber process, wherein the tantalum nitride and subsequently deposited tantalum films/layers can be deposited in two separate chambers, such as IMP or SIP chambers. Still further provided is a method of depositing alpha-tantalum film by depositing PVD tantalum film on CVD films.

### BACKGROUND OF THE INVENTION

1. Field of the Invention

The present invention relates generally to the field of semiconductor manufacturing. More specifically, the present invention relates to a method of obtaining low temperature alpha-Ta thin films using wafer bias.

2. Description of the Related Art

Tantalum (Ta) metal has two crystalline phases: the low resistivity (12-20 micro-ohm-cm) alpha (body centered cubic or bcc) phase and a higher resistivity (160-170 micro-ohm-cm) beta (tetragonal) phase. Due to the lower resistivity of the alpha phase, it is preferred for electronic and semiconductor applications over the beta phase.

Earlier techniques to form this low resistivity phase involved either annealing tantalum films to temperatures over 600° C. for more than 1 hour, or bombarding Ta film with ions t o cause the transformation. These techniques are limited for electronics applications because processing temperatures above 400° C. are typically not compatible with device fabrication. It is also difficult to maintain and control such a high substrate temperature during sputtered metal deposition.

Therefore, the prior art is deficient in the lack of an effective means of depositing an alpha-tantalum film at low temperatures during semiconductor fabrication. Specifically, the prior art is deficient in the lack of an effective means of depositing alpha-tantalum film by using wafer bias. The present invention fulfills this long-standing need and desire in the art.

### SUMMARY OF THE INVENTION

In one aspect of the present invention, there is provided a method of depositing an alpha-tantalum film on a semiconductor wafer. This method comprises the steps of depositing a tantalum nitride film on a wafer; and then depositing a tantalum film over the tantalum nitride film using wafer bias. The tantalum film as deposited is in alpha phase so that an alpha-tantalum film is deposited on the wafer.

In another aspect of the present invention, there is provided a method of depositing a Cu barrier and seed layer on a semiconductor wafer. This method comprises the steps of depositing a tantalum nitride layer on a wafer; depositing a tantalum layer over the tantalum nitride layer using wafer bias, wherein the tantalum layer is in alpha phase, thereby depositing an alpha-Ta barrier layer on the wafer. Subsequently, a Cu seed layer is then deposited over the alpha-tantalum barrier layer.

In still another aspect of the present invention, there is provided a method of depositing an alpha-tantalum film on a semiconductor wafer using a two-chamber process. This method comprises the steps of depositing a tantalum nitride film on a wafer in a first chamber; transferring the wafer deposited with the tantalum nitride film to a second chamber; and depositing a tantalum film over the tantalum nitride film in the second chamber. The tantalum film as deposited is in alpha phase, thereby an alpha-tantalum film is deposited on the wafer.

In yet another aspect of the present invention, there is provided a method of depositing a Cu barrier and seed layer on a semiconductor wafer using a two-chamber process. This method comprises the steps of depositing a tantalum nitride layer on a wafer in a first chamber; transferring the wafer deposited with the tantalum nitride layer to a second chamber; depositing a tantalum layer over the tantalum nitride layer in a second chamber, wherein the tantalum layer is in alpha phase, thereby depositing an alpha-tantalum barrier layer on the wafer; and depositing Cu seed layer over the alpha-tantalum barrier layer.

In still yet another aspect of the present invention, there is provided a method of depositing alpha-tantalum film on a semiconductor wafer. This method comprises the steps of depositing a first film on a wafer in a CVD chamber; transferring the wafer deposited with the first film to a PVD chamber; and depositing a tantalum film over the first film in the PVD chamber. The tantalum film as deposited is in alpha phase, thereby an alpha-tantalum film is deposited on the wafer.

Other and further aspects, features, and advantages of the present invention will be apparent from the following description of the embodiments of the invention given for the purpose of disclosure.

### BRIEF DESCRIPTION OF THE DRAWINGS

So that the matter in which the above-recited features, advantages and objects of the invention, as well as others which will become clear, are attained and can be understood in detail, more particular descriptions of the invention briefly summarized above may be had by reference t o certain embodiments thereof which are illustrated in the appended drawings. These drawings form a part of the specification. It is to be noted, however, that the appended drawings illustrate embodiments of the invention and therefore are not to be considered limiting in their scope.

FIG. 1 shows the result of Scanning Auger analysis of bilayer film demonstrating how the concentration of nitrogen changes from the top of the bilayer film to the bottom. The first part of the film is Ta with ˜13% nitrogen. This is followed by a transition region which corresponds to the interface between the TaN layer and the Ta layer. The third region is the TaN layer which has roughly 25% nitrogen.

FIG. 2 shows the effect of bias used in the tantalum layer (in bilayers) on sheet resistance in the tantalum overlayer. (▴): Peak intensity, (▪): Uniformity, and (♦): Rs. Rs: sheet resistance.

FIG. 3 shows the effect of bias used in the tantalum layer (in bilayers) on nitrogen content in the tantalum overlayer. (▪): Rs., (♦): concentration (%) of nitrogen in tantalum overlayer. Rs: sheet resistance.

FIG. 4 shows the effect of bias used in the tantalum layer (in bilayers) on sheet resistance in the tantalum overlayer, wherein the effects are compared between conditions with Magnet 1 and Magnet 2, separately.

FIG. 5 shows the X-ray defraction (XRD) results demonstrating that alpha-Ta film is formed by depositing PVD Ta on CVD TiSiN. The XRD spectrum shows peaks at 38.5° and 55.6°, which are characteristics of alpha-Ta.

FIG. 6 shows the X-ray defraction (XRD) results demonstrating that alpha-Ta film is formed by depositing PVD Ta on CVD TiN, indicated by the alpha-Ta peaks in the XRD spectrum.

FIG. 7 shows the X-ray defraction (XRD) results demonstrating that a film is formed by depositing PVD Ta on SiO2. No alpha-Ta peaks are found in the XRD spectrum.

### DETAILED DESCRIPTION OF THE INVENTION

The present invention relates to a method of depositing alpha-tantalum films at low temperatures by using wafer bias. This is the first demonstration that wafer bias can be constructively used in obtaining the alpha-phase. The low resistivity (alpha-phase) of the barrier film (Ta) is important for reducing the net resistance of the structure, and providing a better barrier/seed stack for the subsequent electroplating fill process.

The method of one embodiment of the present invention involves depositing a film of TaN, TiSiN or TiN followed by an overlayer of tantalum (Ta). The low resistivity alpha-phase tantalum can be formed by using bias during the step of depositing tantalum overlayer. The tantalum overlayer as deposited has a low concentration of nitrogen that results in the formation of the alpha-phase.

Compared to the state-of-art techniques, the present method by using wafer bias enables the low resistivity alpha-phase tantalum to form at room temperature, which is more compatible with device fabrication than temperatures of over 600° C.

Therefore, as described above, one aspect of the present invention is directed to a method of depositing alpha-tantalum film on a semiconductor wafer. This method comprises the steps of depositing a tantalum nitride film on a wafer; and then depositing a tantalum film over the tantalum nitride film using wafer bias. The tantalum film as deposited is in alpha phase, accordingly, an alpha-tantalum film is deposited on the wafer.

Specifically, the tantalum film is deposited in two steps: depositing a tantalum film over the tantalum nitride film using wafer bias, wherein the tantalum film is in alpha phase; and nucleating the tantalum film. By doing so, an alpha-tantalum film is deposited on the wafer. The wafer bias is from about 100 W to about 500 W, more specifically, from about 300 W to about 500 W. More specifically, the temperature used for depositing the alpha-tantalum film is very much lower than the 600° C. as in prior art techniques, and can be, for example, at room temperature.

Another aspect of the present invention is directed to a method of depositing a Cu barrier and seed layer on a semiconductor wafer. This method comprises the steps of depositing a tantalum nitride layer on a wafer; depositing a tantalum layer over the tantalum nitride layer using wafer bias, wherein the tantalum layer is in alpha phase and thereby depositing an alpha-tantalum barrier layer on the wafer. Subsequently, a Cu seed layer is then deposited over the alpha-tantalum barrier layer.

Specifically, the tantalum layer is deposited in two steps: depositing a tantalum layer over the tantalum nitride layer using wafer bias, wherein the tantalum layer is in alpha phase; and nucleating the tantalum layer. By doing so, an alpha-tantalum layer is deposited on the wafer. The wafer bias is from about 100 W to about 500 W and, more particularly, from about 300 W to about 500 W. More specifically, the temperature used for depositing the alpha-tantalum layer is lower than 600° C., and may be, for example, room temperature.

Still another aspect of the present invention is directed to a method of depositing alpha-tantalum film on a semiconductor wafer using a two-chamber process. This method comprises the steps of depositing a tantalum nitride film on a wafer in a first chamber; transferring the wafer deposited with the tantalum nitride film to a second chamber; and depositing a tantalum film over the tantalum nitride film in a second chamber. The tantalum film as deposited is in alpha phase, thereby an alpha-tantalum film is deposited on the wafer.

Specifically, the first chamber can be an ionized metal plasma chamber, while the second chamber is either an ionized metal plasma chamber or self ionized plasma chamber. Alternatively, both first and second chambers can be self ionized plasma chambers. In this case, the tantalum film is deposited using wafer bias in the second chamber.

Yet another aspect of the present invention is directed to a method of depositing a Cu barrier and a seed layer on a semiconductor wafer using two-chamber process. This method comprises the steps of depositing a tantalum nitride layer on a wafer in first chamber; transferring the wafer deposited with the tantalum nitride layer to second chamber; depositing a tantalum layer over the tantalum nitride layer in second chamber, wherein the tantalum layer is in alpha phase, thereby depositing an alpha-tantalum barrier layer on the wafer; and depositing a Cu seed layer over the alpha-tantalum barrier layer.

Specifically, the first chamber can be an ionized metal plasma chamber, while the second chamber is either an ionized metal plasma chamber or self ionized plasma chamber. Alternatively, both first and second chambers can be self ionized plasma chambers. In this case, the tantalum film is deposited using wafer bias in the second chamber.

Still yet another aspect of the present invention is directed to a method of depositing alpha-tantalum film on a semiconductor wafer. This method comprises the steps of depositing a first film on a wafer in a CVD chamber; transferring the wafer deposited with the first film to a PVD chamber; and depositing a tantalum film over the first film in the PVD chamber. The tantalum film as deposited is in alpha phase, thereby an alpha-tantalum film is deposited on the wafer.

Specifically, the first film may be TiN, TiSiN, TaN, W, or WxN. The PVD chamber is either an ionized metal plasma (IMP) chamber or self ionized plasma (SIP) chamber. Additionally, the wafer is transferred in vacuum from the CVD chamber to the PVD chamber.

The following examples are given for the purpose of illustrating various embodiments of the invention and are not meant to limit the present invention in any fashion.

### EXAMPLE 1

Formation of Alpha Phase Using Bias during the Ta Deposition Step

Five bilayer samples were prepared in the following fashion: 100 Å of TaN was deposited, followed by 150 Å of Ta overlayer, wherein the bias used in the Ta deposition step was varied between 0 W and 500 W. All samples were deposited at room temperature in chambers having vacuum levels of <1×1⁻⁸ Torr by using the physical vapor deposition (PVD) technique. After deposition, the samples were then analyzed for the nitrogen content using the Scanning Auger Technique.

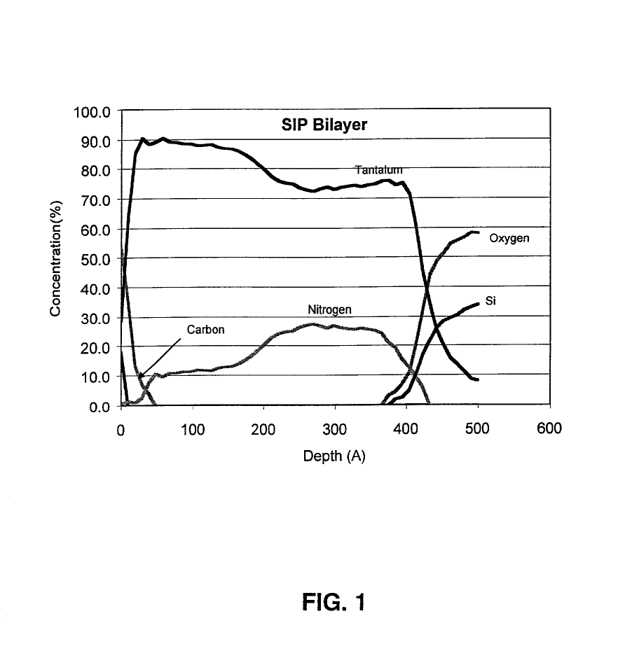

The result shows that the concentration of nitrogen changes from the top of the bilayer film to the bottom (see FIG. 1). The first part of the film is Ta with ˜13% nitrogen. This is followed by a transition region which corresponds to the interface between the TaN layer and the Ta layer. The third region is the TaN layer which has roughly 25% nitrogen.

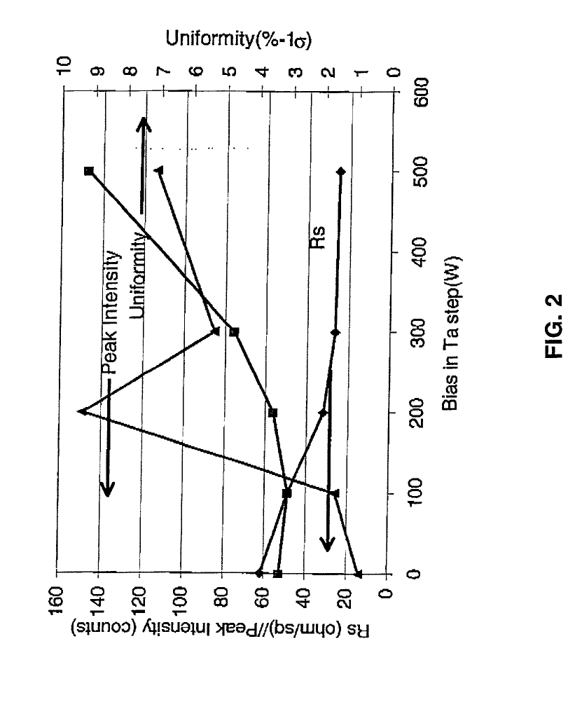

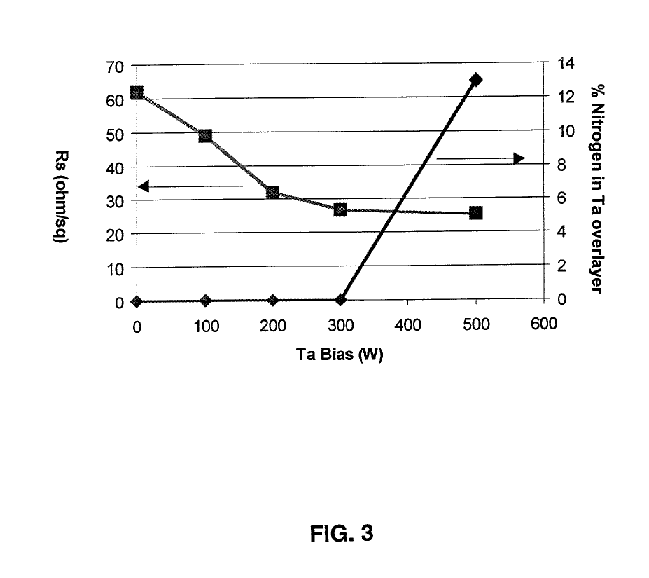

FIG. 2 and FIG. 3 both show that when no bias is used in the tantalum layer (0 W), the alpha phase is not formed (Rs>60 ohm/sq). It was noted that nitrogen is also absent in the tantalum layer at 0 W bias (FIG. 3). This was also confirmed from x-ray diffraction (XRD) studies. Increasing the bias in steps of 100 W, the sheet resistance of the film was observed to come down monotonically till it began to plateau out at ˜25 ohm/square. X-ray diffraction analyses showed that the peak intensity value corresponding to the alpha-phase increased sharply after 100 W. However, no nitrogen was found in the tantalum layer till bias of more than 300 W was used. This indicates that bias is the main factor contributing to the formation of the alpha-phase. The bombardment of high energy ions brought about by bias apparently lead to a transformation of the tantalum phase from beta (tetragonal) to alpha (body centered cubic or bcc). However, it is noted that introduction of small amounts of nitrogen in the tantalum layer (either in the chamber or by some other technique) can actually lead to the formation of the low resistivity alpha phase.

The application of bias used during the x-ray diffraction step facilitates the removal of nitrogen from the underlying TaN layer. However, this happens only at higher bias levels, i.e., >300 W, as seen from FIG. 3.

### EXAMPLE 2

Effect of Magnet on the Ta Phase Formation

The magnet is placed about 1-2 mm above the target (i.e., tantalum film) in a non-vacuum environment. The magnet generates a magnetic field which coupled with the electrical field (the target develops a negative potential due to the applied DC power) accelerates electrons and ions resulting in sputtering the target. The magnet is designed to erode the target as uniformly as possible.

Two magnets were experimented: Magnet 1 and Magnet 2. The two magnets differed in the kind of pole pieces that were used. Certain pole pieces were changed to generate different magnet. Additionally some mechanical design changes also occurred in Magnet 2 compared to Magnet 1. Overall, Magnet 2 is more powerful than Magnet 1 as far as ionization is concerned.

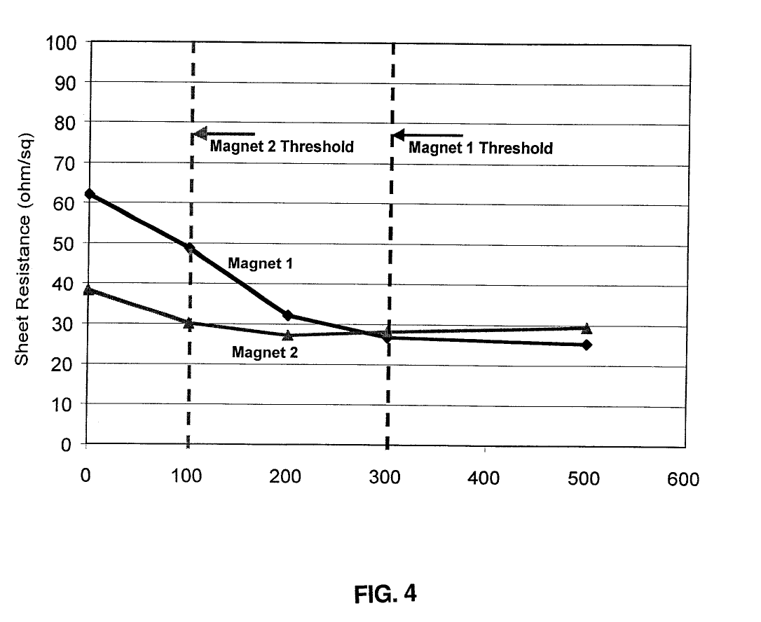

The effect of magnet on the Ta phase formation is shown in FIG. 4. Identical process conditions were used for both Magnet 1 and Magnet 2, and the effect of both magnets were evaluated and compared. Magnet 1 curve reflects the data that were obtained in Example 1.

It is shown that complete formation of the alpha phase in the Ta results in films having a sheet resistance (Rs) of ˜30 ohm/sq or less. For Magnet 1 the threshold bias (during the Ta deposition step) is ˜300 W, while for Magnet 2 the threshold bias is 100 W. These data indicate that by suitably modifying the magnet it is possible to push the threshold Ta bias to lower and lower values.

The magnet used can influence the way plasma couples with the wafer bias. FIG. 4 shows that the alpha phase formation results even at 100 W of bias with Magnet 2, while with Magnet 1 at least 300 W of bias is required. This shows that bias couples better with the plasma for Magnet 2.

### EXAMPLE 3

Effect of Ta Phase on the Ta Layer Subsequently Deposited

In this experiment, two samples were processed. TaN (˜100 Å) was deposited on both wafers with 500 W wafer bias. The process of depositing tantalum overlayer on top of this TaN layer was broken into two steps: a 5-second step (step 1) and a 7-second step (step 2). Sample 1 was processed with no bias in step 1 and with bias in step 2. Sample 2 was processed with bias in step 1 and no bias in step 2. All other processing conditions were the same for both samples.

The experiments in Example 1 demonstrated that use of bias during the tantalum step results in the formation of low resistivity alpha phase and absence of bias results in beta-phase formation. In the present Example, the results demonstrate that once the alpha-phase is formed in the tantalum layer, the subsequent tantalum layer deposited will have the alpha phase in it irrespective of whether bias is used or not (see data from Sample 2, Table 1). In the same vein, once the beta phase is formed in the tantalum layer, the alpha phase will not be formed in the subsequently deposited tantalum layer (see data from Sample 1, Table 1).

TABLE 1
Effect of Ta Phase on the Ta Layer Subsequently Deposited

| | | Step 1 | Step 2 | |
|---|---|---|---|---|
| | Bias-TaN | Bias-Ta | Bias-Ta | Rs |
| Sample | (6.7 s) | (5 s) | (7 s) | (ohm/sq) |
| 1 | 500 W | 0 W | 500 W | 44.16 |
| 2 | 500 W | 500 W | 0 W | 25.94 |

Abbreviations: Rs: sheet resistance.

The above experiments show how alpha or beta tantalum can be grown epitaxially. The conclusion is that not all of the tantalum layers (in a bilayer) need to be deposited with bias in order to form an alpha (or beta) phase. What is needed is a nucleating tantalum layer that already has the alpha phase in it. The rest of the tantalum film deposited on top of this layer will form the alpha phase even if no bias is used.

### EXAMPLE 4

The Effect of a Two Chamber Process on the Formation of the Alpha-Ta Phase

Five different combinations were used to deposit the TaN and tantalum layers. The TaN underlayer was deposited in the IMP (ionized metal plasma) chamber for Samples 1, 2 and 3, while it was deposited in the SIP (self ionized plasma) chamber for Samples 4 and 5. The tantalum over layer was deposited in the self ionized plasma chamber for Samples 1, 2, 4 and 5, while it was deposited in the IMP chamber for Sample 3.

It was observed that the low resistivity alpha-Ta phase forms four of the five combinations (Table 2). While the alpha phase forms only when bias is used during the self ionized plasma Ta step when the underlying TaN was deposited in the self ionized plasma chamber (see Samples 4 & 5), it forms with and without bias when the TaN is deposited in the IMP chamber (see Samples 1 & 2). This indicates that the IMP TaN layer probably has properties that differ from the SIP TaN layer.

TABLE 2
The Effect of a Two Chamber Process on the Formation of
Alpha/Beta-Ta Phase

| Sample | Process | Process | Phase |
|---|---|---|---|
| 1 | IMP TaN (no bias) | SIP Ta (no bias) | alpha |
| 2 | IMP TaN (no bias) | SIP Ta (bias) | alpha |
| 3 | IMP TaN (no bias) | IMP Ta (no bias) | alpha |
| 4 | SIP TaN (bias) | SIP Ta (bias) | alpha |
| 5 | SIP TaN (bias) | SIP Ta (no bias) | beta |

### EXAMPLE 5

Alpha Ta can also be obtained by first depositing TiN or TiSiN in a CVD chamber, then transferring the wafer in vacuum to a PVD Ta chamber (IMP or SIP) for the Ta deposition. TiN film of about 30˜300 Å is deposited in a CVD chamber (e.g., Applied Materials TxZ CVD chamber, U.S. Pat. Nos. 5,846,332 & 6,106,625). The wafer temperature is 350° C. using tetrakis-dimethyl-amido titanium (TDMAT) as precursor. The deposited film is then treated with plasma and SiH4 soak to form TiSiN. Ta of 250 Å is then deposited in IMP Ta chamber with 1 kW target power, 2.5 kW coil power and 350 W wafer bias with 50% duty cycle.

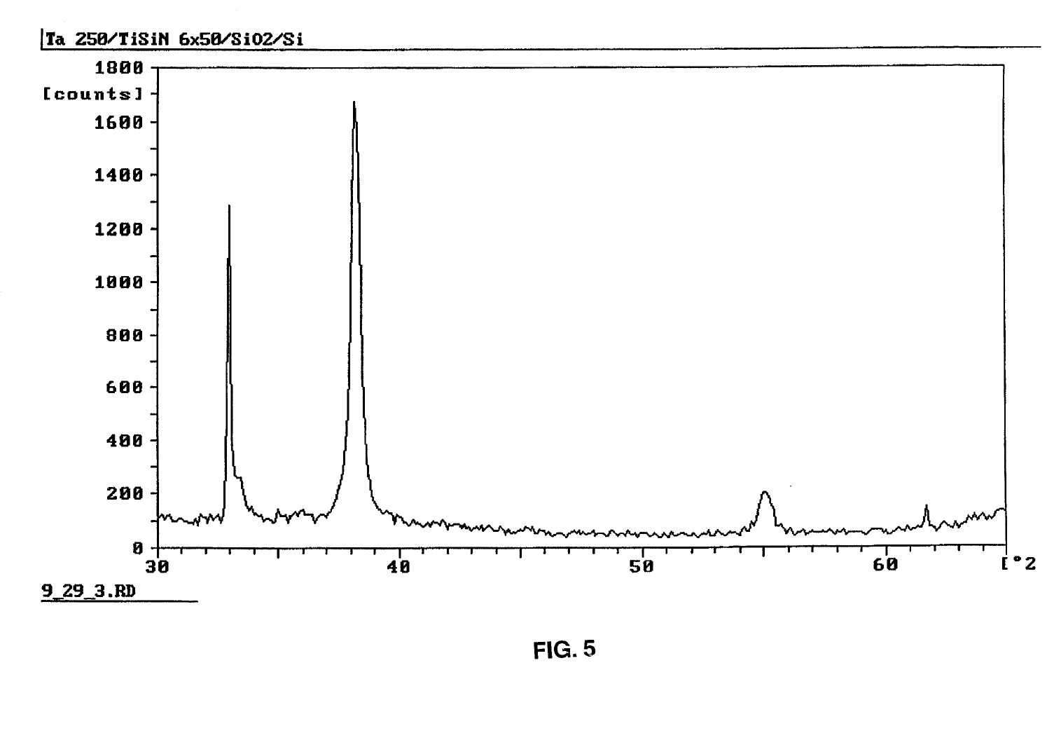

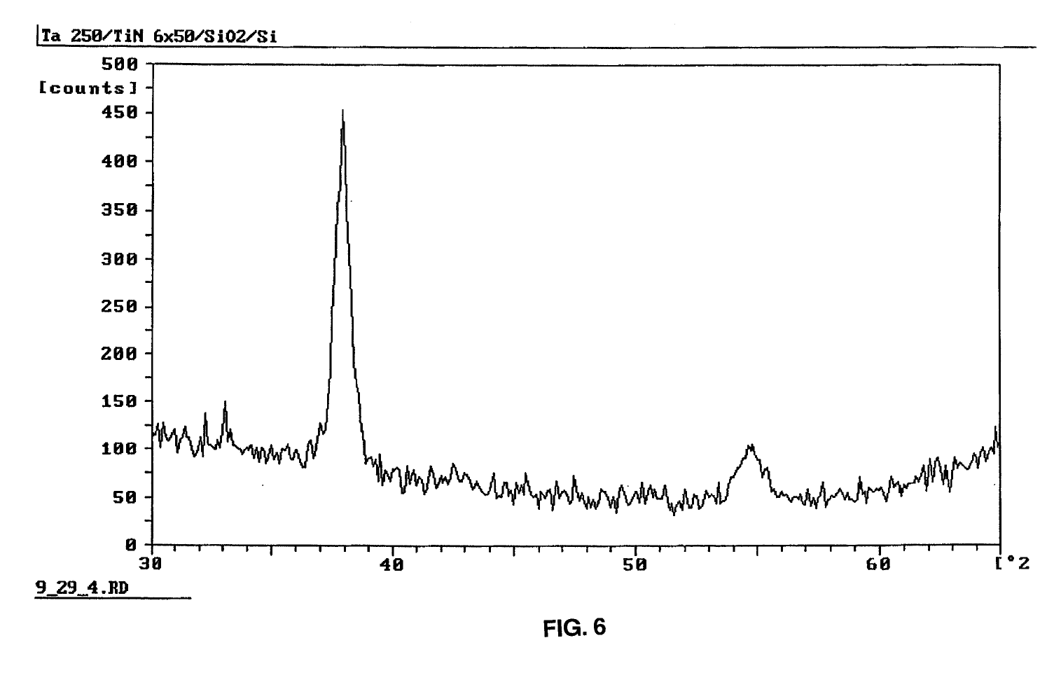

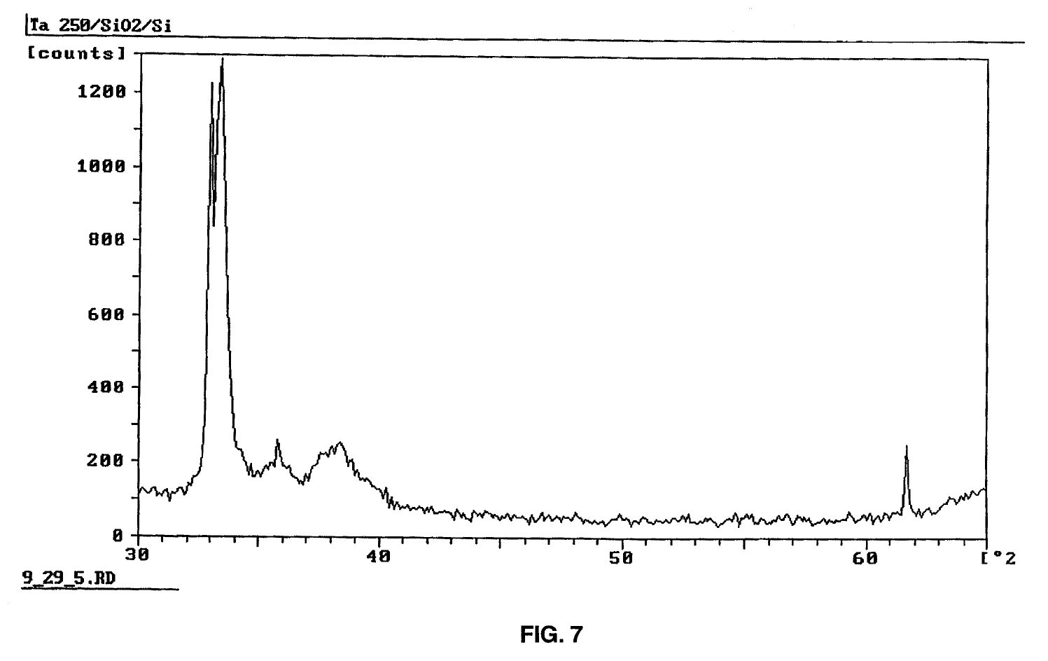

X-ray diffraction (XRD) results showed that the Ta film formed is in alpha phase when PVD Ta is deposited on CVD TiSiN or CVD TiN (FIGS. 5-6), while no alpha-Ta is formed when PVD Ta is deposited on SiO2 (FIG. 7). Besides TiN or TiSiN, the CVD film may also include TaN, W, and WxN.

One skilled in the art will readily appreciate that the present invention is well adapted to carry out the objects and obtain the ends and advantages mentioned, as well as those inherent therein. It will be apparent to those skilled in the art that various modifications and variations can be made in practicing the present invention without departing from the spirit or scope of the invention. Changes therein and other uses will occur to those skilled in the art which are encompassed within the spirit of the invention as defined by the scope of the claims.

What is claimed is:

1. A method of depositing alpha-tantalum film on a semiconductor wafer, comprising the steps of:
depositing a tantalum nitride film on a wafer; and
depositing a tantalum film over said tantalum nitride film using wafer bias, wherein said tantalum film is in alpha phase, so that an alpha-tantalum film is deposited on the wafer.

2. The method of claim 1, wherein said tantalum film deposition step further comprising the steps of:
depositing a tantalum film over the tantalum nitride film using wafer bias, wherein said tantalum film is in alpha phase; and
nucleating said tantalum film, thereby an alpha-tantalum film is deposited on the wafer.

3. The method of claim 2, wherein said wafer bias is from about 100 W to about 500 W.

4. The method of claim 3, wherein said wafer bias is from about 300 W to about 500 W.

5. The method of claim 1, wherein said alpha-tantalum film is deposited at a temperature of lower than 600° C.

6. The method of claim 5, wherein said alpha-tantalum film is deposited at room temperature.

7. A method of depositing a Cu barrier and seed layer on a semiconductor wafer, comprising the steps of:
depositing a tantalum nitride layer on a wafer;
depositing a tantalum layer over said tantalum nitride layer using wafer bias, wherein said tantalum layer is in alpha phase, thereby depositing an alpha-tantalum barrier layer on the wafer; and
depositing Cu seed layer over said alpha-tantalum barrier layer, thereby Cu barrier and seed layer is deposited on the wafer.

8. The method of claim 7, wherein said tantalum layer deposition step further comprising the steps of:
depositing a tantalum layer over the tantalum nitride layer using wafer bias, wherein said tantalum layer is in alpha phase; and
nucleating said tantalum layer, thereby an alpha-tantalum layer is deposited on the wafer.

9. The method of claim 8, wherein said wafer bias is from about 100 W to about 500 W.

10. The method of claim 9, wherein said wafer bias is from about 300 W to about 500 W.

11. The method of claim 7, wherein said alpha-tantalum barrier layer is deposited at a temperature of lower than 600° C.

12. The method of claim 11, wherein said alpha-tantalum barrier layer is deposited at room temperature.

13. A method of depositing alpha-tantalum film on a semiconductor wafer, comprising the steps of:
depositing a tantalum nitride film on a wafer in a first chamber;
transferring the wafer deposited with said tantalum nitride film to a second chamber; and
depositing a tantalum film over said tantalum nitride film in said second chamber, wherein said tantalum film is in alpha phase, thereby an alpha-tantalum film is deposited on the wafer.

14. The method of claim 13, wherein said first chamber is ionized metal plasma chamber, and said second chamber is selected from the group consisting of ionized metal plasma chamber and self ionized plasma chamber.

15. The method of claim 13, wherein said tantalum film is deposited using wafer bias in said second chamber.

16. The method of claim 15, wherein said first and second chambers are self ionized plasma chambers.

17. A method of depositing a Cu barrier and a seed layer on a semiconductor wafer, comprising the steps of:
depositing a tantalum nitride layer on a wafer in a first chamber;
transferring the wafer deposited with said tantalum nitride layer to a second chamber;
depositing a tantalum layer over said tantalum nitride layer in said second chamber, wherein said tantalum layer is in alpha phase, thereby depositing an alpha-tantalum barrier layer on the wafer; and
depositing Cu seed layer over said alpha-tantalum barrier layer, so that said Cu barrier and said seed layer is deposited on the wafer.

18. The method of claim 17, wherein said first chamber is ionized metal plasma chamber, and said second chamber is selected from the group consisting of ionized metal plasma chamber and self ionized plasma chamber.

19. The method of claim 17, wherein said tantalum film is deposited using wafer bias in said second chamber.

20. The method of claim 19, wherein said first and second chambers are self ionized plasma chamber.

21. A method of depositing alpha-tantalum film on a semiconductor wafer, comprising the steps of:
depositing a first film on a wafer in a CVD chamber;
transferring the wafer deposited with said first film t o a PVD chamber; and
depositing a tantalum film over said first film in said PVD chamber, wherein said tantalum film is in alpha phase, thereby an alpha-tantalum film is deposited on the wafer.

22. The method of claim 21, wherein said first film is selected from the group consisting of TiN, TiSiN, TaN, W, and WxN.

23. The method of claim 21, wherein said PVD chamber is an ionized metal plasma chamber or self ionized plasma chamber.

24. The method of claim 21, wherein the wafer deposited with said first film is transferred in vacuum to said PVD chamber.
